(19) United States
(12) Patent Application Publication
(10) Pub. No.: US 2012/0227789 A1
(43) Pub. Date: Sep. 13, 2012

(54) Solar Collector Comprising Receiver Positioned External to Inflation Space of Reflective Solar Concentrator

(75) Inventors: Robert L. Lamkin, Pleasanton, CA (US); David S. Finley, Berkeley, CA (US)

(73) Assignee: COOLEARTH SOLAR, Livermore, CA (US)

(21) Appl. No.: 13/227,093

(22) Filed: Sep. 7, 2011

Related U.S. Application Data
(60) Provisional application No. 61/381,842, filed on Sep. 10, 2010.

(51) Int. Cl. G02B 7/188; H01L 31/052

(52) U.S. Cl. 136/246; 359/847

(57) ABSTRACT

Embodiments of the present invention utilize inflation air to impart an appropriate shape to a reflective concentrator of a solar collector device. An optical receiver or a secondary optic in communication with an optical receiver may be positioned outside the concentrator's internal inflation space in a plane containing a substantially circular pattern of concentrated reflected illumination. In certain embodiments, the inflation space may be defined between the reflective film having a concave shape, and an optically transparent thin film adopting a convex shape in response to the inflation pressure. In some embodiments the inflation space may be defined between the concave reflective film, and an optically transparent disk having a thickness resisting internal inflation pressure to adopt a planar or only slightly convex profile.

### CROSS-REFERENCE TO RELATED APPLICATIONS

This application claims the benefit of U.S. Provisional Appln. No. 61/381,842, filed Sep. 10, 2010, which is incorporated herein by reference in its entirety for all purposes.

### BACKGROUND

Solar radiation is the most abundant energy source on earth. However, attempts to harness solar power on large scales have so far failed to be economically competitive with most fossil-fuel energy sources.

One reason for the lack of adoption of solar energy sources on a large scale is that fossil-fuel energy sources have the advantage of economic externalities, such as low-cost or cost-free pollution and emission. Political solutions have long been sought to right these imbalances.

Another reason for the lack of adoption of solar energy sources on a large scale is that the solar flux is not intense enough for direct conversion at one solar flux to be cost effective under most circumstances. Solar energy concentrator technology has sought to address this issue.

Specifically, solar radiation is one of the most easy energy forms to manipulate and concentrate. It can be refracted, diffracted, or reflected, to many thousands of times the initial flux, utilizing only modest materials.

With so many possible approaches, there have been a multitude of previous attempts to implement low cost solar energy concentrators. So far, however, solar concentrator systems cost too much to compete directly with fossil fuels, in part because of excessive material and large areas that that solar collectors occupy. These excessive materials that are used and the large areas that are occupied by solar concentration systems render them unsuitable for large-scale solar farming.

Accordingly, there is a need in the art to reduce costs and maximize the scale of solar power plants through the use of elements employing minimal materials and low-cost materials, which are able to be mass produced with existing technology, making them less expensive and better able to compete economically with existing fossil fuels.

### SUMMARY

Embodiments of the present invention utilize inflation air to impart an appropriate shape to a reflective concentrator of a solar collector device. An optical receiver or a secondary optic in communication with an optical receiver may be positioned outside the concentrator's internal inflation space in a plane containing a substantially circular pattern of concentrated reflected illumination, hereafter referred to as “the Spot”. In certain embodiments, the inflation space may be defined between the reflective film having a concave shape, and an optically transparent thin film adopting a convex shape in response to the inflation pressure. In some embodiments the inflation space may be defined between the concave reflective film, and an optically transparent disk having a thickness resisting internal inflation pressure to adopt a planar or only slightly convex profile.

### BRIEF DESCRIPTION OF THE DRAWINGS

A further understanding of the nature and advantages of the disclosure may be realized by reference to the remaining portions of the specification and the drawings, presented below. The figures are incorporated into the detailed description portion of the disclosure.

FIG. 1 shows a simplified cross-sectional view of an embodiment of an inflated solar power collector in accordance with the present invention.

FIGS. 2A-2D shows simplified cross-sectional views of rays reflected from an embodiment of an inflated solar power collector in accordance with the present invention.

FIGS. 2EA-2EB show simplified cross-sectional views of rays reflected from solar power collectors inflated to exhibit different focal ratios.

FIG. 3 shows a simplified cross-sectional view of an alternative embodiment of an inflated solar power collector in accordance with the present invention.

FIG. 4 shows an enlarged cross-sectional view of the embodiment of FIG. 1, showing examples of instances of concentrated and reflected irradiance.

### DETAILED DESCRIPTION

Certain embodiments of the present invention seek to reduce the levelized cost of energy of a solar power plant, and to maximize the scale at which such plants can be deployed. Embodiments of solar collector devices and methods in accordance with the present invention may be utilized in conjunction with power plants as is recognized by those skilled in the art.

The objectives of reduced levelized cost and maximized scale of a solar power plant, can be achieved through the use of elements employing minimal materials and low-cost materials, that are able to be mass produced with existing technology. Potentially desirable attributes of various elements of such a solar power plant, include simple and rapid accurate installation and assembly, ease of maintenance, robustness, favorable performance at and below certain environmental conditions such as a design wind speed, and survivability at and below a higher maximum wind speed.

Costs of major structures of a solar power plant may be economically externalized. For example, particular embodiments of the present invention may seek to exploit spontaneous and natural tendencies of materials. One instance is the tendency of a flat reflective film to assume a smooth concave shape under inflation pressure.

Thus according to certain embodiments of the present invention, inflation air may be used to impart a curved profile to a reflective component of a concentrator for a solar collector structure. Incorporated by reference in their entireties herein for all purposes, are the following patent applications: U.S. Patent Publication No. 2008/0047546 disclosing an inflatable solar concentrator balloon method and apparatus; and U.S. patent application Ser. No. 13/015,339 filed on Jan. 27, 2011 disclosing an inflated concentrator structure. Embodiments of the present invention may share one or more characteristics in common with the apparatuses disclosed in one or both of these patent applications.

The smooth, concave shape adopted by a planar reflective film under inflation pressure, is not parabolic or an ideal shape. Rather, the surface offered by such a concave shape has previously been described by Hencky, and is hereafter referred to as a Hencky surface. Background information regarding the shape of a Hencky surface, is described by Marker and Jenkins in “Surface precision of optical membranes with curvature”, OPTICS EXPRESS Vol. 1, No. 11 (1997), which is hereby incorporated by reference in its entirety for all purposes.

Rather than focusing reflected light on a single focal point (as expected by a parabolic reflective surface), the Hencky surface focuses and concentrates light nonuniformly within a spatial region. As this spatial region lies well outside the internal inflation space of the concentrator, the receiver is positioned outside the concentrator in a plane containing a corresponding instance of the Spot.

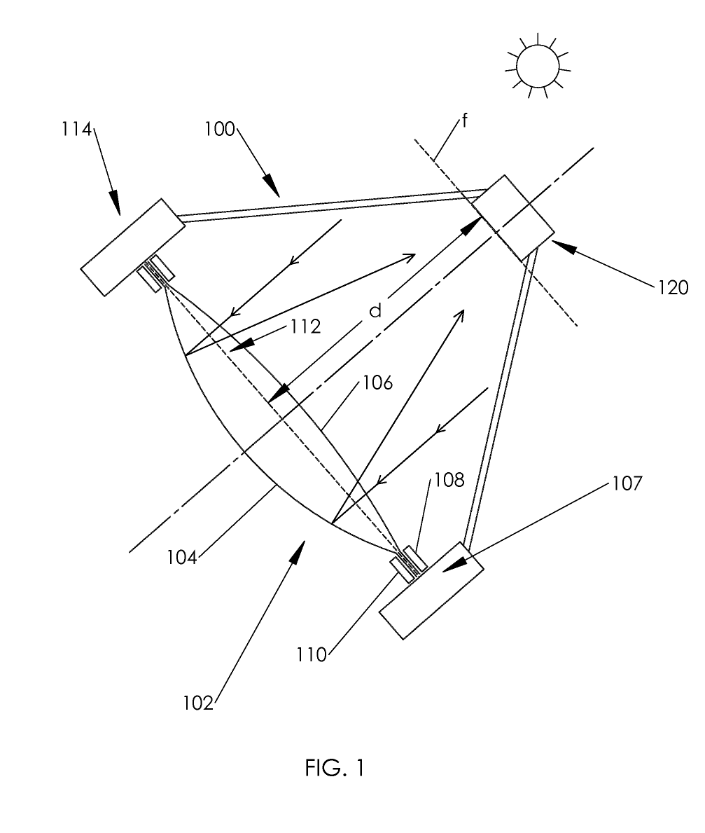

FIG. 1 shows a simplified cross-sectional view of an embodiment of an inflated solar power collector, in accordance with the present invention. Collector 100 comprises concentrator 102 formed by a first lower reflective film 104 sealed at its circumference with a second upper transparent film 106, utilizing a harness structure 107 that may be comprised of two rings 108 and 110 that are secured together, for example by continuous or discrete fasteners such as clips or bolts or screws. The reflective film 104 may include aluminum or another reflective material. Provision of gas into the inflation space 112 between the sealed films, forms a lenticular inflated concentrator structure.

In operation, a 2-axis tracking structure 114 may be employed to maintain alignment of the concentrator with respect to the direction of light rays from the sun. Examples of support and tracking structures for embodiments of solar collectors according to the present invention are described in detail in U.S. patent application Ser. No. 13/015,339 filed on Jan. 27, 2011. In addition, U.S. Patent Publication No. 2008/0168981 describes examples of rigging systems for supporting and pointing solar concentrator arrays. Both of these patent applications are incorporated by reference in their entireties herein for all purposes. Embodiments of apparatuses according to the present invention, may share certain features disclosed in one or both of these patent applications.

Light incident from the sun passes through the upper transparent film 106, is reflected off of the lower reflective film 104, and is accordingly focused and concentrated. As is described below, the nature of inflation of the concentrator (for example its inflation pressure) can serve to maintain and control the optic focus of the lens formed by the concentrator. Upper transparent film 106 and lower reflective film 104 can also include an ultraviolet (UV) protective material to help prevent breakdown of the films when exposed to sun light. In some embodiments the upper transparent film 106 and the lower reflective film 104 include the UV protective material in the film itself whereas in other embodiments the UV protective material is applied as a protective overcoat on the films.

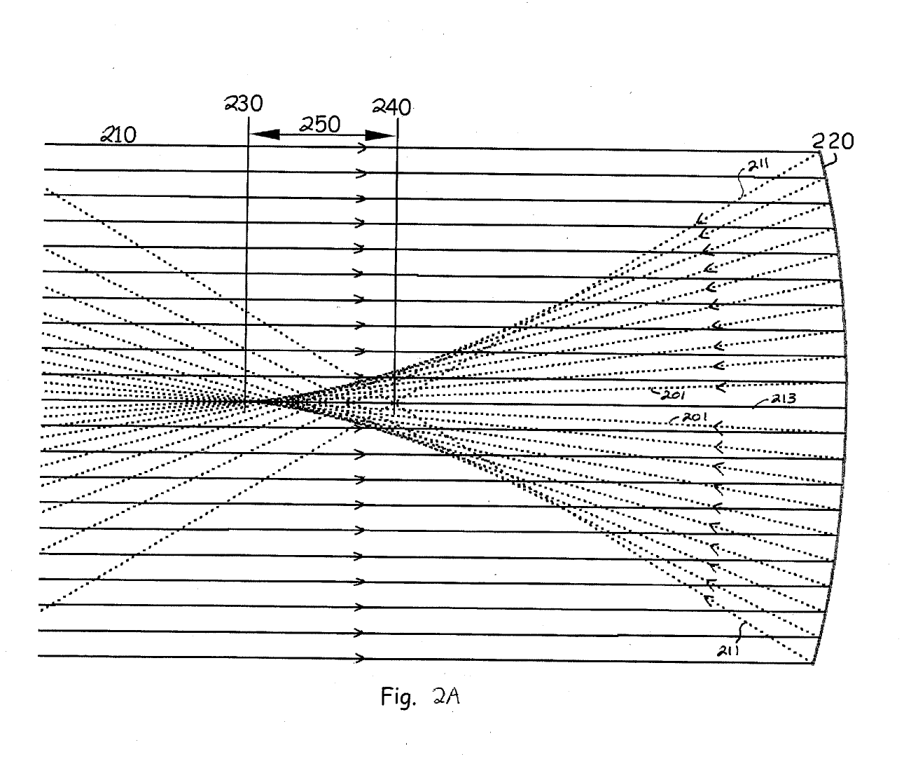

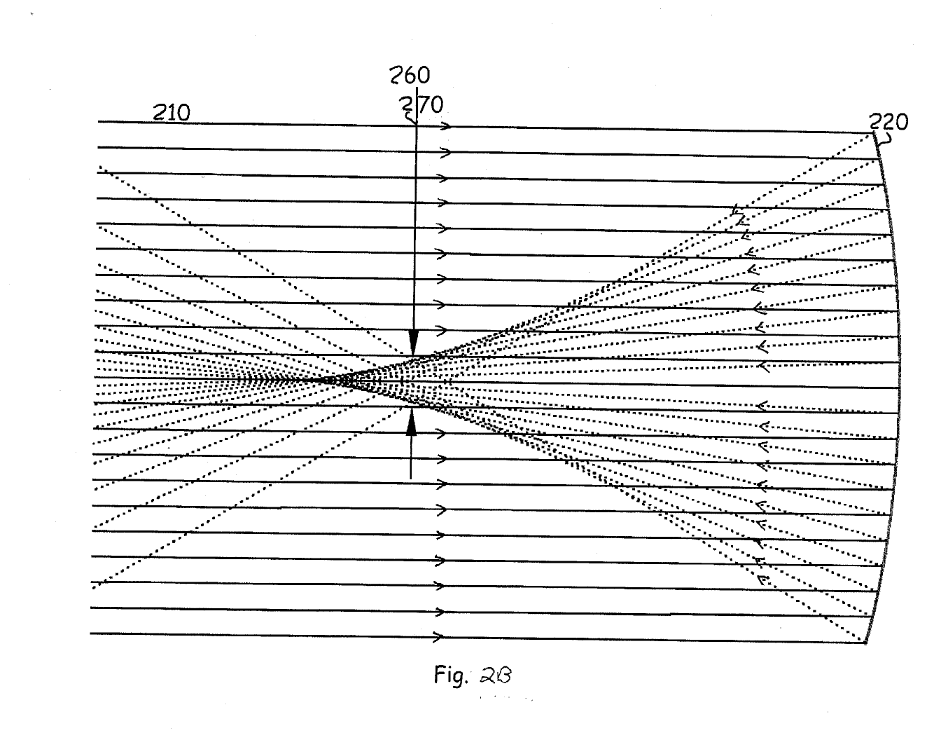

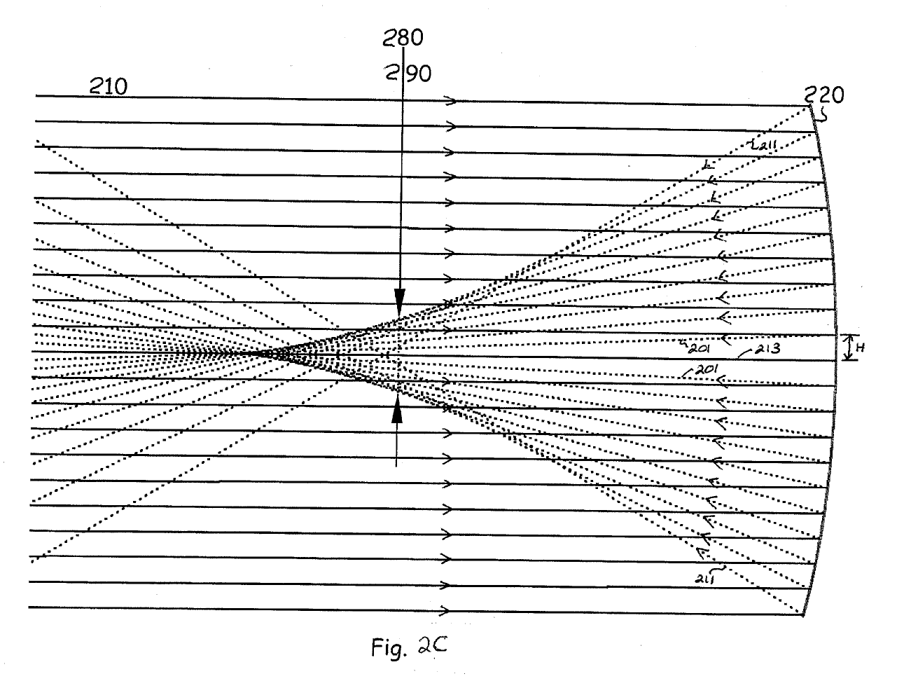

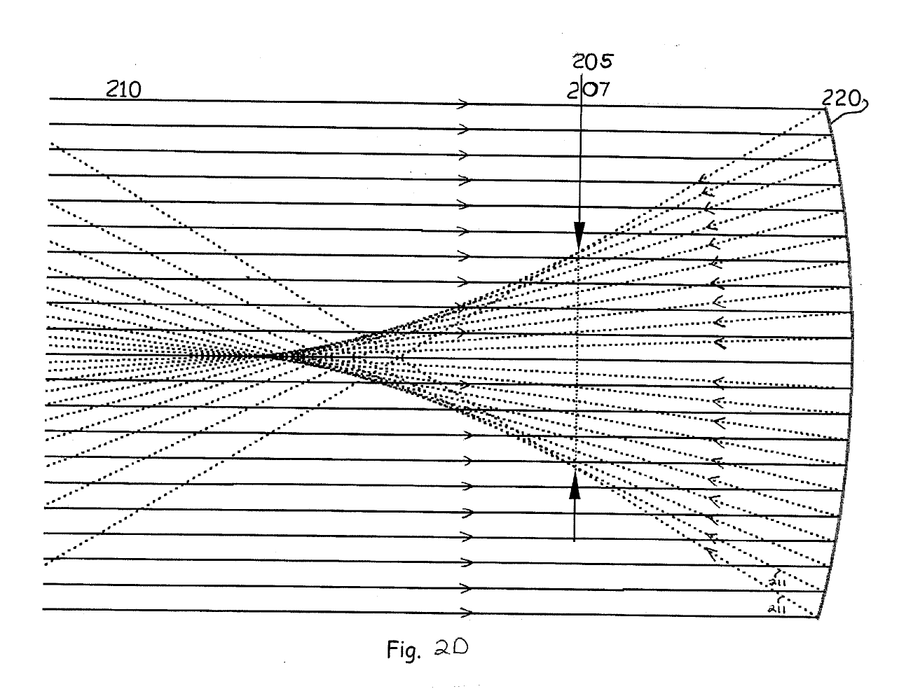

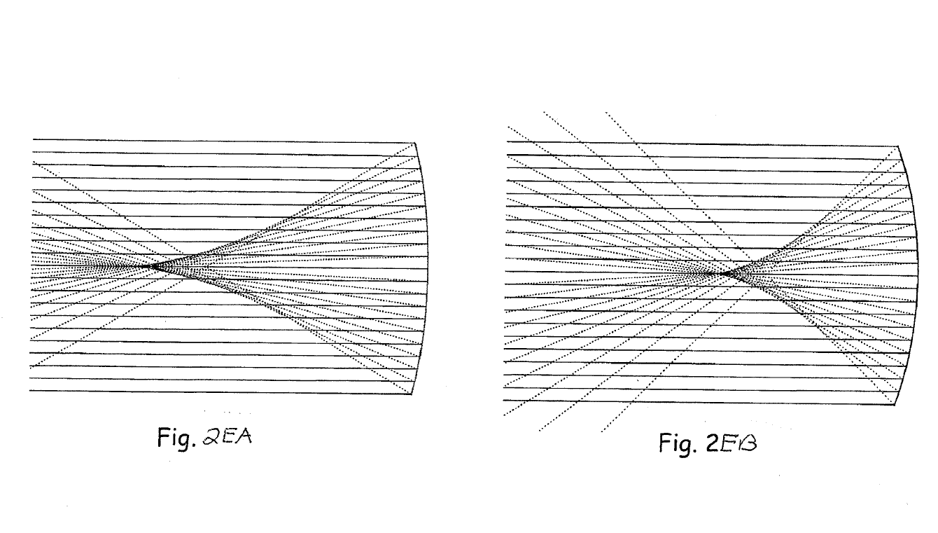

FIGS. 2A-2D show concentration of incident solar rays by a reflective Hencky surface. FIG. 2A shows that incident rays 210 from the sun strike the inflated reflective concentrator 220 and converge toward focii located in the spatial region lying between plane 230 and the marginal ray focal plane 240. In particular, paraxial rays 201 converge to a focus in plane 230. Marginal rays 211 converge to a focus in the marginal ray focal plane 240. Rays that are between paraxial and marginal, converge at intermediate focii located in planes of the spatial region lying between plane 230 and the marginal ray focal plane 240. In some embodiments, the reflective concentrator 220 is the same as reflective film 104 of concentrator 102 and, also, the same as reflective film 304 of concentrator 302.

The separation between the plane 230 and the marginal ray focal plane 240 along the optical axis 213, as indicated by the distance 250, is a measure of the longitudinal aberration of the system. Such longitudinal aberration is a common measure of the deviation from ideal focus for optical systems in general.

FIG. 2B indicates the plane 270 containing the “circle of least confusion.” This circle of least confusion represents the smallest spot containing essentially all of the direct irradiance solar rays specularly reflected from the concentrator 220. The circle of least confusion has the diameter indicated by the distance 260.

As used herein, direct irradiance solar rays exclude those rays that are scattered by the atmosphere, and which are incident to the concentrator at different angles. As used herein, specularly reflected rays exclude the small fraction of rays that are scattered from the concentrator 220.

The circle of least confusion 270 represents one possible location for placement of a receiver or secondary optic in a collector system utilizing an inflatable concentrator. According to certain embodiments, positioning of a thermal receiver in the plane containing the circle of least confusion may be favored, because this plane has the highest concentration of energy with no loss of energy. An example of a receiver or secondary optic that can be placed in the circle of least confusion 270 is the receiver 120 illustrated in FIG. 1.

In other embodiments, however, the plane containing the circle of least confusion may not represent the optimal location for positioning of a receiver. For example, certain embodiments of the present invention may employ a receiver comprising a photovoltaic (PV) array and secondary optic.

Incorporated by reference in its entirety herein for all purposes, is U.S. Pat. No. 7,866,035 issued on Jan. 11, 2011 and U.S. Provisional Patent Application No. 61/475,483 filed on Apr. 14, 2011, which discloses photovoltaic or thermal receivers for cost-effective solar energy conversion of concentrated light. U.S. patent application Ser. No. 12/720,429 filed on Mar. 9, 2010, also incorporated by reference in its entirety herein for all purposes, describes certain optical structures, including secondary optics. Embodiments of apparatuses according to the present invention may share features with those disclosed in one or both of these patent applications.

Placement of a PV receiver in the plane containing the circle of least confusion 270 may not be preferred due to the range of ray angles intercepting this plane at any point on the plane. For example, those rays incident at angles exceeding the angular acceptance of a secondary optic will be lost, reducing efficiency of the collector.

FIG. 2C indicates a plane 290 which forms a spot of diameter 280. This spot exhibits the property whereby the marginal ray 211 crosses the paraxial ray 201 before crossing the optical axis 213. This plane 290 lies closer to the concentrator 220 along the optical axis than does the marginal ray focal plane 240.

The location of plane 290 is determined in part by the radial distance from the optical axis of the paraxial ray from the optical axis. The radial distance from the optical axis of the paraxial ray is in turn determined by the radial distance from the optical axis to the edge of the receiver (not shown in FIGS. 2A-2D, but shown in FIG. 1) that forms an occlusion in the optical path. In particular, the first paraxial ray that hits the concentrator 220 optic must first clear the receiver.

Plane 290 is not generally referenced in the art. As used herein, this plane 290 will be referred to herein as the “one-cross plane.” This is because the marginal ray 211 crosses each of the other rays once, and just crosses the paraxial ray in this plane. This paraxial ray is the one nearest to the optical axis that also clears the receiver.

FIG. 2D indicates a plane 205 having a diameter 207. Plane 205 lies in an area where the marginal rays 211 cross.

Rays in planes closer to the concentrator 220 than plane 240 form a spot with the highest uniformity of irradiance. However, rays in this region may typically exhibit a much lower concentration of sun light.

In addition, the rays in plane 205 may suffer from losses due to the large occlusion factor of the receiver. Specifically, the larger the size of the receiver the greater the optical losses attributable to rays hitting the back of the receiver prior to having a chance to hit the concentrator 220.

Thus according to certain embodiments of the present invention, an optimal position for a photovoltaic receiver, which may incorporate a cellular optic, may lie between the plane 205 and a plane somewhat beyond the marginal focal plane 240. According to some embodiments, a photovoltaic receiver may be positioned in a plane occupying this region and lying near the one-cross plane 290.

When designing a solar photovoltaic collection system, an operating concentration is selected based upon a particular cell type. For example, silicon cells operate in the range of 1× through 350×. GaAs cells operate in the range 1× through more than 2000×, and typically in the range 500× through 1000×.

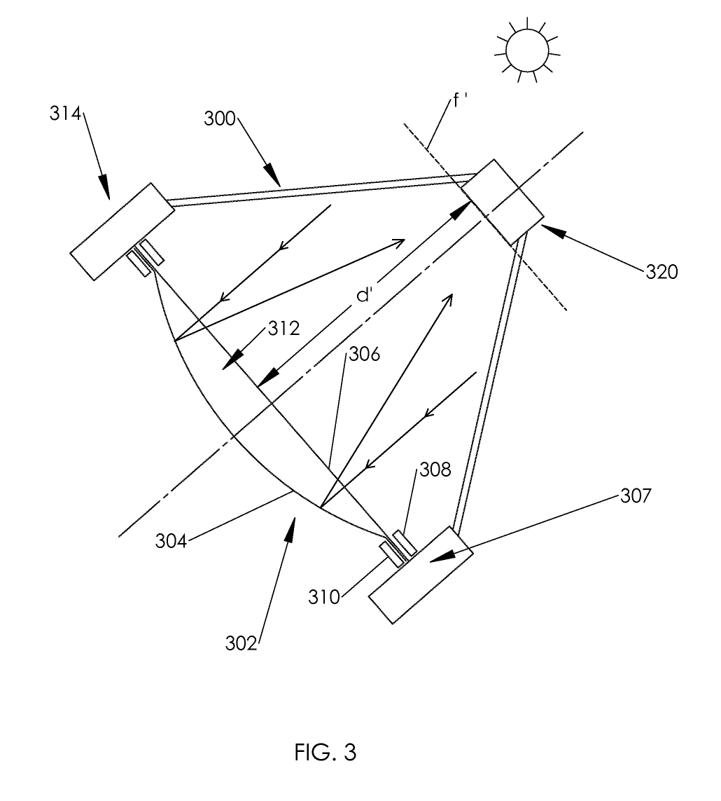

Once a net concentration is selected, that quantity is divided between the primary optic (the concentrator formed by the inflated film, as illustrated in FIGS. 1 and 3 as 104 and 304, respectively) and any secondary optic. Thus, for example, if the target concentration is 100×, that quantity may be divided between 33× by the primary optic, and multiplicative 3× by the secondary optic.

Specifically, it is desirable to steer light toward active areas of the receiver and away from non-active areas of the receiver. Non-active areas of the receiver can include margins of devices, metallization, and space between devices. Accordingly, a secondary optic may exhibit a concentration ratio of at least the ratio of: active area/total area. Thus in this example, if one third of the area of the receiver is active, the secondary optic must concentrate at least 3×.

The location of the secondary optic (or receiver itself if no such secondary optic is present) is known as the working distance. The working distance may be measured along the optical axis, from the plane occupied by a reflective film undeformed by inflation pressure. For example, in FIG. 1 the working distance is labeled as “d” and extends from the inflation space 112 to the receiver 120.

Thus, continuing with an example where the target concentration is 100×, a combination of film gauge and inflation pressure could be used to achieve a spot with a net concentration of 33× (including optical losses), chosen for a particular working distance. The balance of the 100×, 3×, would be in the secondary optic.

Selection of the working distance may represent a trade-off between a number of factors, including but not limited to spot quality (which is generally better for longer working distances), angles of incidence, and the practical aspects of mounting the receiver. If the working distance is too long, structural considerations (such as member length, and the mass required to provide cantilever support) may undesirably drive up cost.

A focal ratio provides a typical range of practical values for the working distance. As used herein, the term focal ratio refers to the ratio of:

the working distance of the receiver/the concentrator diameter of the reflective film.

Embodiments according to the present invention may position the secondary optic or receiver at a distance corresponding to a focal ratio lying between about f/0.5 and f/2.5. Various embodiments of the present invention could position a receiver and/or secondary optic at a working distance based upon a focal ratio falling into one or more of the following ranges:

f/0.5-f/2.5; f/0.75-f/2.0; f/0.9-f/1.5; f/0.9-f/2.5; f/1.5-f/2.5; f/2.0-f/2.5.

Focal ratios longer than f/2.5 are possible. However, longer focal ratios may tend to drive up structural costs, because of the added strength needed to support the receiver at a long working distance.

Conversely, focal ratios shorter than f/0.5 are also possible, but the higher aberrations at lower focal ratios tend to render difficult the effective design of an efficient secondary optic, or require that too many rays are allowed to miss the receiver, again increasing cost. Focal ratios substantially shorter than f/0.5 may also result in the receiver lying within the inflation space of the inflated solar power concentrator. However, given the geometry of the inflated films, working distances at the minimum focal ratio of f/0.5 could still be expected to lie outside the internal inflation space of the inflated solar power concentrator. However, focal ratios shorter than f/0.5 are also possible with film modifications as described in U.S. Provisional Patent Application No. 61/428,203, filed on Dec. 29, 2010, which is hereby incorporated by reference for all purposes.

Returning to the embodiment of FIG. 1, the receiver 120 (which may include a secondary optic) is positioned at or proximate to a plane f that is at working distance d from the inflated concentrator, corresponding to the desired focal ratio. The receiver is configured to convert the reflected and concentrated solar energy into other form(s) of energy.

According to some embodiments, the receiver 120 may comprise a photovoltaic (PV) structure that is configured to convert solar energy into electrical energy. Such a PV receiver may be water- or air-cooled.

In certain embodiments, the receiver 120 may comprise a concentrated solar power (CSP) structure that is configured to convert solar energy into thermal energy of a working fluid having a desirable heat characteristics. Examples of such working fluids may include water, oils, salts, or other materials. New engineered energy storage materials are becoming available that can be “charged” or can be made to store energy either by heating or by being irradiated by photons. The energy can later be released by use of catalysts or other controllable processes. A “receiver” could also be used that charges an energy storage material with the concentrated sunlight from the concentrator system in this application so that the energy can be stored and released at another time or place. In other embodiments, usable liquid or gaseous fuels can be created by cracking large, complex molecules with the addition of heat and/or light. The feedstock molecules may not be suitable for use as a fuel until they are cracked and separated into useful components. Concentrated light from the system in this application could be used to crack bio-based, petroleum based or other molecules to make useful fuels.

Solar collector devices as disclosed herein may be modular in nature. For example, in some embodiments the concentrator structure 102 comprising films 104 and 106 and harness 107, or in some embodiments the concentrator structure 302 comprising film 304 and disk 306 and harness 307, may comprise a cartridge that is readily removed from the remaining elements of the collector (such as the receiver and supporting/tracking elements), in order to facilitate inspection, maintenance, and/or replacement of the individual components (such as films) of the concentrator structure. Moreover, the discrete nature of such a modular concentrator ‘cartridge’ may facilitate its periodic transport to other locations, for the performance of such inspection/maintenance/replacement activities.

The precise location of the plane of the receiver outside of the inflation space, can vary depending upon the particular embodiment. In particular, a combination of factors can influence the focal distance exhibited by the inflated concentrator. One example of such a factor is the dimensions of the inflated concentrator, such as diameter if circular in shape, or length of major/minor axes if elliptical in shape, as the focal distance equals the specified focal ratio times the concentrator diameter as defined above. In FIG. 1 and FIG. 3, this focal distance is shown as dimension d and d′, respectively.

Another factor influencing the location of planes containing a preferred instance of the Spot is the shape of the concentrator once inflated. This inflated shape, in turn, is affected by factors such as inflation pressure, and the nature of the materials forming the concentrator. Examples of such material characteristics include thickness, composition, and elasticity/plasticity in response to applied inflation pressure.

FIGS. 2EA-2EB show simplified cross-sectional views of rays reflected from solar power collectors inflated to exhibit different focal ratios. In particular, FIG. 2EA shows the path of rays of the system of FIGS. 2A-D previously described.

By contrast, FIG. 2EB shows an inflated concentrator operating at a shorter focal ratio, with a more strained film, than the embodiment of FIG. 2EA. Such a shorter focal ratio may be achieved utilizing a higher inflation pressure, a lower gauge film, or some combination of these factors.

In one embodiment, the lower reflective film 104 comprises a film of polyethylene terephthalate (PET) having a diameter of about 3 m and a thickness of about 23 um. Under an internal inflation pressure of about 250 Pa, the lower reflective film 104 is expected to experience a substantially elastic deformation of about 1% strain and about 200 mm displacement.

The upper optically transparent film 106 comprises a film of PET having a diameter of about 3 m and a thickness of about 23 um. Under the internal inflation pressure of about 250 Pa, the upper transparent film is expected to experience a substantially elastic deformation of about 1% strain and about 200 mm displacement.

In view of the above parameters, this particular embodiment of an inflated lenticular concentrator would be expected to exhibit a working distance of 2.7 m of which about 2.5 m would lie outside of the inflation space. In such an example, a receiver positioned at or near the Spot would be exposed to a reflected solar image having a focal ratio increased by factor of 2 with a commensurate improvement in the Spot compared to a design whereby the receiver is constrained to be disposed between the upper and lower films.

As mentioned above, the ability to collect a high quality spot of reflected illumination is one potential benefit offered by embodiments in accordance with the present invention. Another possible advantage is increased performance resulting from a reduction in the magnitude of the incident angles of reflected solar rays.

Specifically, a longer working distance increases the focal ratio of the system and reduces the incident angle of the marginal ray from the reflective concentrator to the receiver. This reduction in incident angle allows for the collection of larger amounts of light through total internal reflection by a secondary optic, which in glass is limited to light rays with incident angles of 48° or less. This limit is determined by the TIR angular limit for a glass TIR secondary optic with an index of ˜1.5 and max angle of total internal reflection of 48 degrees.

Still another possible advantage offered by embodiments of the present invention is increased performance resulting from a reduction in the range of incident angles of reflected solar rays. Specifically, a longer working distance increases the focal ratio of the system and reduces the range of incident angles as the arctangent of the inverse of the focal ratio. This reduction in incident angle ranges allows for use of a secondary optic that is specially-designed to capture light over this range of incidence angles, thereby increasing collection performance.

Yet another possible advantage offered by embodiments according to the present invention, is a lowered strain on the components of the concentrator, thereby resulting in longer expected operational lifetimes. Specifically, a longer working distance increases the focal ratio of the system and reduces the incident angle of the marginal ray from the reflective concentrator to the receiver. As the magnitude of the marginal ray angle is determined by the strain in the plastic film, embodiments of the present invention allow correspondingly reduced strain (as may be achieved by use of a lower inflation pressure and/or a thicker film).

Such reduced inflation pressure requires less energy to achieve, thereby facilitating set-up of the apparatus. Moreover, reduced inflation pressure may result in reduction of the strain on the films of the concentrator. A high level of strain is undesirable, in that it can induce film creep, fatigue, specular reflectance loss, and possible rupture, thereby limiting the operational lifetime of the concentrator.

A further possible benefit offered by embodiments of the present invention, is enhanced access to the receiver structure. In particular, placement of the receiver outside of the inflation space, allows the receiver to be inspected or removed without affecting the inflation state of the concentrator element. Again, such modularization of collector components may facilitate maintenance activities, reducing downtime and costs associated therewith.

Moreover, improved access to the receiver offered by embodiments of the present invention, may also permit the use of improved designs. For example, location of a receiver well outside the inflation space, may facilitate its connection with fluid sources for cooling (in the case of a PV receiver), or for the conveyance of thermal energy in the form of a working fluid (in the case of a CSP receiver). U.S. Patent Publication No. 2008/0057776, disclosing interconnection systems for solar energy modules and ancillary equipment, including fluid conduits, is hereby incorporated by reference in its entirety for all purposes.

While FIG. 1 depicts a collector comprising a concentrator having an inflation space defined between lower film 104 and upper film 106 exhibiting concave and convex profiles respectively, the present invention is not limited to this particular embodiment. Alternative embodiments could employ different concentrator designs and remain within the scope of the present invention.

For example, FIG. 3 shows a simplified cross-sectional view of an alternative embodiment of an inflated solar power collector in accordance with the present invention. As with the embodiment of FIG. 1, collector 300 comprises concentrator 302 formed by a first lower reflective film 304 having a concave profile and sealed at its circumference and utilizing a harness structure 307 that may be comprised of two rings 308 and 310 that are secured together, for example by continuous or discrete fasteners such as clips or bolts or screws. The reflective film 304 may include aluminum or another reflective material. Provision of gas into the inflation space 312 forms a lenticular inflated concentrator structure.

Unlike the embodiment of FIG. 1, however, the reflective film is sealed at its circumference with a disc 306 comprising a layer of transparent material having a relatively large thickness as compared with a film. For example, in certain embodiments the layer of transparent material may comprise PET or poly(methyl methacrylate) (PMMA) or polycarbonate (PC). Examples of thicknesses of layers of such materials useful in accordance with the present invention include from about 0.5-75 mm, depending on material strength and collector diameter.

The thickness of the material of the upper disc 306 allows it to resist the internal inflation pressure while experiencing little or no physical deformation. Accordingly, application of inflation pressure into the space 312 between reflective film 304 and transparent disc 306, results in an inflated concentrator offering a relatively flat upper profile.

For example, where the lower reflective film 304 comprises a disk of PET having a diameter of about 3 m and a thickness of about 23 um. Under an internal inflation pressure of about 250 Pa, the lower reflective film 304 is expected to experience a substantially elastic deformation of about 1% strain.

In this embodiment, the upper optically transparent component comprises a disk 306 of PMMA having a diameter of about 3 m and a thickness of about 10 mm. Under the internal inflation pressure of about 250 Pa, the upper transparent layer or disk 306 experiences a negligible plastic or elastic deformation, resulting in the plane f containing the Spot lying a distance d′ of about 2.5 m outside of the inflation space.

By utilizing a rigid, thick disk for the upper (transparent) element of the concentrator, the embodiment of FIG. 3 may offer certain benefits. One advantage is a reduction in optical losses and hence improved performance of the collector device.

Specifically, the thickness of the upper plate or disk 306 may have a lifetime far exceeding that of the thinner, and relatively more fragile transparent thin film 106 used in the embodiment of FIG. 1. This longer expected lifetime would encourage more investment in the properties of such a disk, in contrast with a clear transparent thin film that is expected to be replaced much more frequently.

For example, a rigid transparent disk 306, according to embodiments of the present invention, may include an anti-reflective component, such as an anti-reflective coating (ARC) or an anti-reflective substance that is incorporated within the material comprising the optically transparent disk. Examples of such anti-reflective components include, but are not limited to, ¼ wave coatings of a low-refractive index material such as magnesium fluoride (MgF₂) or multiple layer coatings of two or more metal oxides (i.e. MgF₂ and titanium oxide (TiO)) to achieve an even lower reflection and/or reduced reflection over a larger wavelength region than a simple single layer ¼ wave MgF₂ coating.

Other examples of coatings include bulk coatings of low-index materials. Although some of these coatings may be less effective as an AR coating, they may be preferable because they offer the advantage of reduced cost. Coatings can incorporate additional properties, such as anti-scratch and/or hydrophobic character for reduced dirt buildup and easier cleaning.

Such an anti-reflective component could serve to reduce reflection of incident light by the upper (transparent) component of the concentrator. The reduced reflection would allow the collection of light that would otherwise be lost to reflection, thereby improving the performance of the device. For example, the use of an anti-reflective component in an upper disk of a collector, could reduce expected optical losses from around 4% per surface (total 8% single pass, 16% double pass) to around 0.5% per surface (total 1% single pass, 2% double pass) in an embodiment comprising PMMA as an optically transparent material and a single coating of MgF₂ in an n1+¼ wave coating.

In some embodiments, the thinner optically transparent film 106 illustrated in FIG. 1 also includes an anti-reflective component.

Use of a transparent disk 306 having greater thickness than a thin film could also reduce optical losses by being easier to clean. In particular, the surface of the disk could exhibit sufficient stiffness to resist forces associated with cleaning that could otherwise puncture or damage a thin film.

Another advantage associated with the embodiment of FIG. 3, is a reduction in the material needed to support the concentrator. In particular the reduced vertical profile offered by the upper surface of the concentrator resulting from the flat upper panel, could decrease the magnitude of forces from wind loading. Such reduction in wind loading forces would in turn allow use of a support member having less mass.

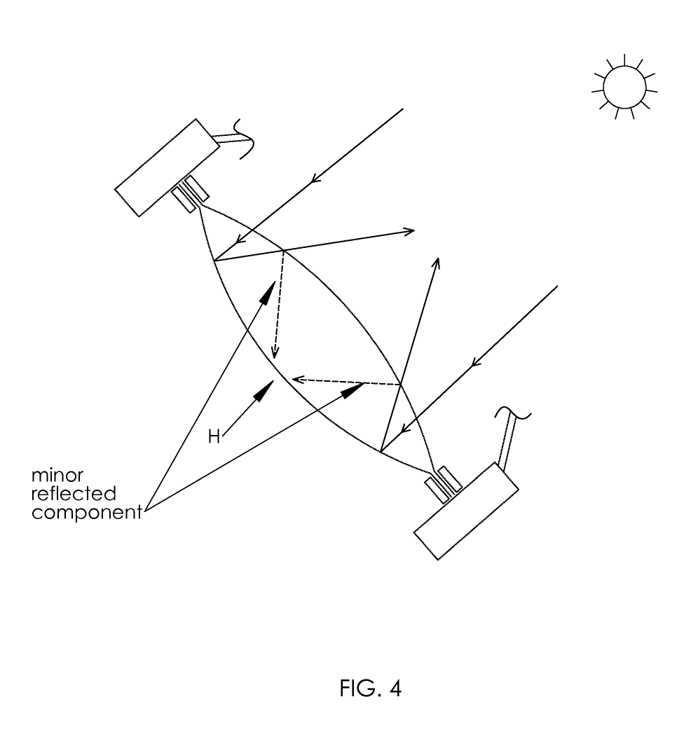

As depicted in FIG. 4, the bowed shape of the upper transparent film may impart an unwanted focusing effect upon light arriving from the bottom film, and reflected by the upper film. Such unwanted focusing, even of a minor reflected component of the light communicated through the concentrator, can give rise to areas of concentrated irradiance H (‘Hot Spots’) on the bottom reflective film or on the clear film. Such Hot Spots can potentially reduce the durability and lifetime of the lower reflective film. Therefore, in some embodiments the upper transparent film is selected to minimize the amount of light that is reflected off its surface facing the lower reflected film and maximize the amount of light that is transmitted through the film in this direction.

By contrast, the upper transparent surface of the thicker disk of the embodiment of FIG. 3, experiences little or no bowing in response to an internal inflation pressure. Such a substantially planar shape of the upper transparent layer is not conducive to the formation of Hot Spots by unwanted reflective focusing.

A further advantage of the embodiment contained in FIG. 3, is reduced distortion in the Spot. Specifically, in the embodiment of FIG. 1, the rings 108 and 110 supporting the two thin films are not radially constrained, a condition which may allow radial deformations that result in distortion of the Spot. By contrast, the thicker front disk of the embodiment of FIG. 3 is not subject to radial distortions in rings 308 and 310, which in turn helps to maintain symmetry of the Spot.

As described above, the concave Hencky-type surface offered by a reflective film deformed by inflation pressure, deviates in shape from a parabola. Thus, such a reflective surface does not tend to focus reflected light to a single focal point.

According to certain embodiments, however, the upper transparent layer of the inflated concentrator structure is designed to compensate for such deviation from the ideal parabolic shape, thereby allowing concentrated light formed by reflection to focus and create a Spot having higher quality.

As shown in FIG. 3, the profile of the Hencky-type surface 304 of the deformed reflective film, departs from a parabolic shape. However, the upper transparent layer 306 of the concentrator may impart a change in the optical path of the light, to compensate for this deviation. In this manner, the reflected light may be caused to converge upon a focal point F as would be expected of an ideal parabolic shape. The intensity and uniformity of the resulting Spot of reflected and concentrated radiation, may improve the efficiency of collection of solar energy.

The transparent upper layer 306 in FIG. 3 includes at least one optical surface that alters the optical path of the light in two separate passes. The properties of this optical surface 306 can be designed to accordingly take into account the cumulative effect of these two encounters.

As previously describes a single optical surface can be used to focus light. However, in other embodiments, more than one optical surface can be used to focus the light. For example, the desired focusing can be achieved by shaping both surfaces of transparent layer 306 to operate in a cumulative manner over the two passes of light traveling through the inflated concentrator.

As shown in the embodiment of FIG. 3, where change in optical path is imparted by a single optical surface, that optical surface could be one surface of a thick, rigid disk, with the other surface of the rigid disc being a simple planar surface.

In an embodiment, an apparatus includes an optically transparent layer, a reflective film secured at an edge to the optically transparent layer, an inflation space between the reflective film and the optically transparent layer the inflation space including a gas having a pressure that deforms the reflective film to locate a substantially circular pattern of concentrated reflected illumination in a plane outside of the inflation space, and an optical element positioned in the plane to receive light reflected by the reflective film.

In an embodiment, the plane of the apparatus is disposed at a working distance based on a focal ratio of the reflective film. The focal ratio ranges from f/0.5-f/2.5, the focal ratio is substantially equal to the working distance/the concentrator diameter of the reflective film, and the working distance is measured from the location of the reflective film in an undeformed state.

In an embodiment, the optical element includes a photovoltaic receiver.

In an embodiment, the optical element includes a secondary optic.

In an embodiment, the optically transparent layer includes a transparent film deformed by the gas pressure.

In an embodiment, the optically transparent layer includes a transparent disc that is not substantially deformed by the gas pressure.

In an embodiment, the optically transparent layer further includes an anti-reflective component.

In an embodiment, the optically transparent layer is secured to the edge of the reflective film by a harness including a first ring joined to a second ring.

In an embodiment, the apparatus further includes a tracking system in physical communication with the harness.

In an embodiment, the receiver includes a thermal receiver located proximate to a circle of least confusion.

In an embodiment, the optically transparent layer includes an optical surface configured to compensate for deviation of the distorted reflective film from a parabolic shape.

In an embodiment, a method includes flowing a pressurized gas into an inflation space between an optically transparent layer and a reflective film secured at an edge to the optically transparent layer, such that a gas pressure within the inflation space deforms the reflective film, reflecting incident solar energy off of the reflective film to form a substantially circular pattern of concentrated reflected illumination in a plane located outside the inflation space, and positioning an optical element proximate to the plane to convert the solar energy into another form of energy. The plane can be disposed at a working distance based on a focal ratio of the reflective film, the focal ratio can range from f/0.5-f/2.5, the focal ratio can be substantially equal to the working distance/the concentrator diameter of the reflective film, and the working distance is measured from the location of the reflective film in an undeformed state.

In an embodiment, positioning the optical element includes positioning a photovoltaic receiver to convert the solar energy into electrical energy.

In an embodiment, positioning the optical element includes positioning a secondary optic in optical communication with a receiver.

In an embodiment, the optically transparent layer includes an optically transparent film whose shape is deformed by the gas pressure.

In an embodiment, the optically transparent layer includes an optically transparent disk whose shape is not substantially deformed by the gas pressure. The optically transparent layer can include an anti-reflective component.

Although specific embodiments of the invention have been described, various modifications, alterations, alternative constructions, and equivalents are also encompassed within the scope of the invention. The described invention is not restricted to operation within certain specific embodiments, but is free to operate within other embodiments configurations as it should be apparent to those skilled in the art that the scope of the present invention is not limited to the described series of transactions and steps.

It is understood that all material types provided herein are for illustrative purposes only. Accordingly, reflective films can be made of various different reflective materials such as materials comprising polyethylene terephthalate (PET), as described in some the embodiments herein. Similarly, transparent films can be made of various transparent material such as materials comprising PET or poly(methyl methacrylate) (PMMA) or polycarbonate (PC), as described in some the embodiments herein.

The specification and drawings are, accordingly, to be regarded in an illustrative rather than a restrictive sense. It will, however, be evident that additions, subtractions, deletions, and other modifications and changes may be made thereunto without departing from the broader spirit and scope of the invention as set forth in the claims.

What is claimed is:

1. An apparatus comprising:
an optically transparent layer;
a reflective film secured at an edge to the optically transparent layer;
an inflation space between the reflective film and the optically transparent layer the inflation space comprising a gas having a pressure that deforms the reflective film to locate a substantially circular pattern of concentrated reflected illumination in a plane outside of the inflation space; and
an optical element positioned in the plane to receive light reflected by the reflective film.

2. The apparatus of claim 1 wherein:
the plane is disposed at a working distance based on a focal ratio of the reflective film, wherein:
the focal ratio ranges from f/0.5-f/2.5;
the focal ratio is defined as the working distance/a concentrator diameter of the reflective film; and
the working distance is measured from a location of the reflective film in an undeformed state.

3. The apparatus of claim 1 wherein the optical element comprises a photovoltaic receiver.

4. The apparatus of claim 1 wherein the optical element comprises a secondary optic.

5. The apparatus of claim 1 wherein the optically transparent layer comprises a transparent film deformed by the gas pressure.

6. The apparatus of claim 1 wherein the optically transparent layer comprises a transparent disc that is not substantially deformed by the gas pressure.

7. The apparatus of claim 1 wherein the optically transparent layer further comprises an anti-reflective component.

8. The apparatus of claim 1 wherein the optically transparent layer is secured to the edge of the reflective film by a harness comprising a first ring joined to a second ring.

9. The apparatus of claim 8 further comprising a tracking system in physical communication with the harness.

10. The apparatus of claim 1 wherein the receiver comprises a thermal receiver located proximate to a circle of least confusion.

11. A method comprising:
flowing a pressurized gas into an inflation space between an optically transparent layer and a reflective film secured at an edge to the optically transparent layer, such that a gas pressure within the inflation space deforms the reflective film;
reflecting incident solar energy off of the reflective film to form a substantially circular pattern of concentrated reflected illumination in a plane located outside the inflation space; and
positioning an optical element proximate to the plane to convert the solar energy into another form of energy.

12. The method of claim 11 wherein:
the plane is disposed at a working distance based on a focal ratio of the reflective film, wherein:
the focal ratio ranges from f/0.5-f/2.5;
the focal ratio is defined as the working distance/a concentrator diameter of the reflective film; and
the working distance is measured from a location of the reflective film in an undeformed state.

13. The method of claim 11 wherein positioning the optical element comprises positioning a photovoltaic receiver to convert the solar energy into electrical energy.

14. The method of claim 11 wherein positioning the optical element comprises positioning a secondary optic in optical communication with a receiver.

15. The method of claim 11 wherein positioning the optical element comprises positioning a thermal receiver to convert the solar energy into thermal energy.

16. The method of claim 11 wherein the optically transparent layer comprises an optically transparent film whose shape is deformed by the gas pressure.

17. The method of claim 11 wherein the optically transparent layer comprises an optically transparent disk whose shape is not substantially deformed by the gas pressure.

18. The method of claim 11 wherein the optically transparent layer comprises an anti-reflective component.
